(19) United States
(12) Patent Application Publication
(10) Pub. No.: US 2025/0378128 A1
(43) Pub. Date: Dec. 11, 2025

(54) ANALYSIS APPARATUS, ANALYSIS METHOD, AND PROGRAM

(71) Applicant: INTER-UNIVERSITY RESEARCH INSTITUTE CORPORATION RESEARCH ORGANIZATION OF INFORMATION AND SYSTEMS, Tokyo (JP)

(72) Inventors: Ichiro HASUO, Tokyo (JP); James HAYDON, Tokyo (JP)

(21) Appl. No.: 19/307,462

(22) Filed: Aug. 22, 2025

Related U.S. Application Data
(63) Continuation of application No. PCT/JP2024/004987, filed on Feb. 14, 2024.

(30) Foreign Application Priority Data
Feb. 28, 2023 (JP) 2023-030334

(51) Int. Cl. G06F 17/10

(52) U.S. Cl. CPC G06F 17/10

(57) ABSTRACT

An analysis apparatus includes an inputter configured to receive an input of a first temporal logic formula and an input of a second temporal logic formula, and an outputter configured to output a screen for displaying a first block diagram showing the first temporal logic formula and a second block diagram showing the second temporal logic formula in a comparable manner.

### CROSS-REFERENCE TO RELATED APPLICATIONS

This application is a continuation application of International Application No. PCT/JP2024/004987 filed on Feb. 14, 2024, and designated the U.S., which is based upon and claims priority to Japanese Patent Application No. 2023-30334 filed on Feb. 28, 2023, the entire contents of which are incorporated herein by reference.

### BACKGROUND

### 1. Technical Field

The present disclosure relates to an analysis apparatus, an analysis method, and a program.

### 2. Description of Related Art

In a product design process in the manufacturing industry, for example, temporal logic formulae that can express properties of time-series data have been attracting significant attention. For example, “Symbolic Monitoring Against Specifications Parametric in Time and Data” (Masaki Waga, Etienne Andre, and Ichiro Hasuo, C A V 2019, LNCS 11561, pp. 520-539, 2019) (hereinafter, “Non-Patent Document 1”) discloses an algorithm configured to address events or properties relevant in product design by describing such events or properties using temporal logic formulae.

### SUMMARY

According to one aspect of the present disclosure, an analysis apparatus includes an inputter configured to receive an input of a first temporal logic formula and an input of a second temporal logic formula, and an outputter configured to output a screen for displaying a first block diagram showing the first temporal logic formula and a second block diagram showing the second temporal logic formula in a comparable manner.

### BRIEF DESCRIPTION OF THE DRAWINGS

FIG. 1 is a block diagram illustrating an example of an overall configuration of a temporal logic formula analysis system;

FIG. 2 is a block diagram illustrating an example of a hardware configuration of a computer;

FIG. 3 is a block diagram illustrating an example of a functional configuration of the temporal logic formula analysis system;

FIG. 4 is a diagram illustrating an example of an analysis screen;

FIG. 5 is a diagram illustrating an example of an output block;

FIG. 6 is a diagram illustrating an example of a display area;

FIG. 7 is a diagram illustrating an example of another display area; and

FIG. 8 is a flowchart illustrating an example of analysis processing.

### DETAILED DESCRIPTION

Although the use of temporal logic formulae has attracted significant attention, expressing events or properties using such formulae remains nontrivial. One reason is the lack of tools capable of showing temporal logic formulae in a developer-friendly mode.

According to one aspect of the present disclosure, an analysis apparatus capable of efficiently analyzing temporal logic formulae is provided.

Each embodiment of the present disclosure will be described hereinafter with reference to the accompanying drawings. In the present specification and the drawings, components having substantially the same functional configuration will be denoted by the same reference numerals and thus repeated descriptions will be omitted.

### EMBODIMENT

An embodiment of the present disclosure is a temporal logic formula analysis system that provides an analysis tool for analyzing temporal logic formulae. Temporal logic formulae are a language that can express properties of time-series data.

Temporal logic formulae are suitable for describing goals in data analysis or model analysis. Goals in data analysis or model analysis can be, for example, “To investigate whether a certain property holds in a certain system” or “To optimize a certain system so that a certain property holds”. To describe a goal similar to these examples in C, for example, several hundred to several thousand lines of code are required. With temporal logic formulae, on the other hand, it is possible to describe such a goal in at most a few lines of code.

Expression (1) is an example of a temporal logic formula. Expression (1) describes an event in automobile control, for example, “If the engine speed (rpm) exceeds 3500 when the gear is in first gear, the gear switches to second gear within 1 second”.

$$G ( gear = 1 ∧ rpm > 3500 ⇒ {F}_{[ 0 , 1 ]} gear = 2 ) \qquad ( 1 )$$

For example, in a product design process in manufacturing industry, many analysis tasks arise at various stages. Examples of analysis tasks in a product design process include mining specific events from big data and determining parameter values to satisfy specific properties.

Temporal logic formulae have attracted attention as a formal language for describing “desirable events or properties” or “hazardous events or properties that need to be addressed” in analysis tasks. In recent years, algorithms have been proposed to solve analysis tasks at high speed and fully automatically by describing such events or properties using temporal logic formulae (see, for example, Non-Patent Document 1).

However, in order to apply an algorithm using temporal logic formulae, it is necessary to describe, using temporal logic formulae, an event or property conceptualized by the developer and intended to be formally specified. However, it is not straightforward to accurately describe an event or property using temporal logic formulae. For example, the question such as “Does a given temporal logic formula indicate semantic meaning as intended by the developer?” is a difficult question that has no clear answer. In order to solve this problem, there is a need for an analysis tool that explains or exemplifies semantic meaning of a given temporal logic formula so that the developer can easily understand it, and proposes revisions as necessary.

The temporal logic formula analysis system of the present embodiment aims to provide an analysis tool that can efficiently analyze temporal logic formulae. In particular, the temporal logic formula analysis system of the present embodiment aims to realize a user interface that can display temporal logic formulae in a mode that facilitates user understanding.

### <Overall Configuration of Temporal Logic Formula Analysis System>

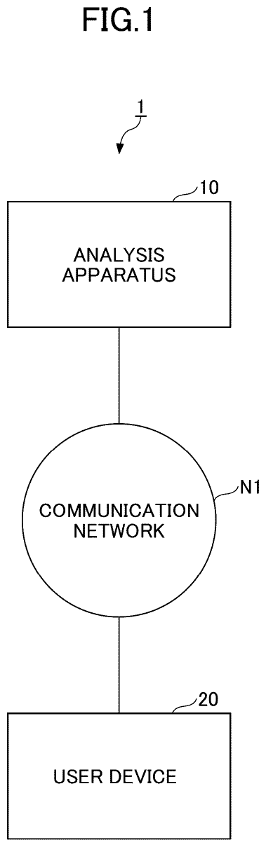

An overall configuration of the temporal logic formula analysis system of the present embodiment will be described with reference to FIG. 1. FIG. 1 is a block diagram illustrating an example of the overall configuration of the temporal logic formula analysis system of the present embodiment.

As illustrated in FIG. 1, the temporal logic formula analysis system 1 of the present embodiment includes an analysis apparatus 10 and a user device 20. The analysis apparatus 10 and the user device 20 are connected in such a manner that they exchange data with each other via a local area network (LAN) or a communication network N1 such as the Internet.

The analysis apparatus 10 is an information processing device that provides an analysis tool for analyzing temporal logic formulae, such as a personal computer, a workstation, or a server. The analysis apparatus 10 receives a temporal logic formula to be analyzed from the user device 20 and transmits an analysis result of the temporal logic formula to the user device 20.

The user device 20 is an information processing terminal device that is operated by a user of the analysis tool, such as a personal computer, a smartphone, or a tablet-type device. The user of the analysis tool is, for example, a developer who develops a specific system using temporal logic formulae. The user device 20 transmits a temporal logic formula that is input by the user to the analysis apparatus 10 and causes the analysis tool to display the analysis result received from the analysis apparatus 10.

The overall configuration of the temporal logic formula analysis system 1 illustrated in FIG. 1 is merely an example, and various system configurations can be used depending on use and purpose. For example, one or more of the analysis apparatus 10 and one or more of the user device 20 may be included in the temporal logic formula analysis system 1. For example, the analysis apparatus 10 may be implemented by multiple computers or may be implemented as a cloud computing service. Classifying apparatuses as the analysis apparatus 10 and the user device 20 as illustrated in FIG. 1 is merely an example.

### <Hardware Configuration of Temporal Logic Formula Analysis System>

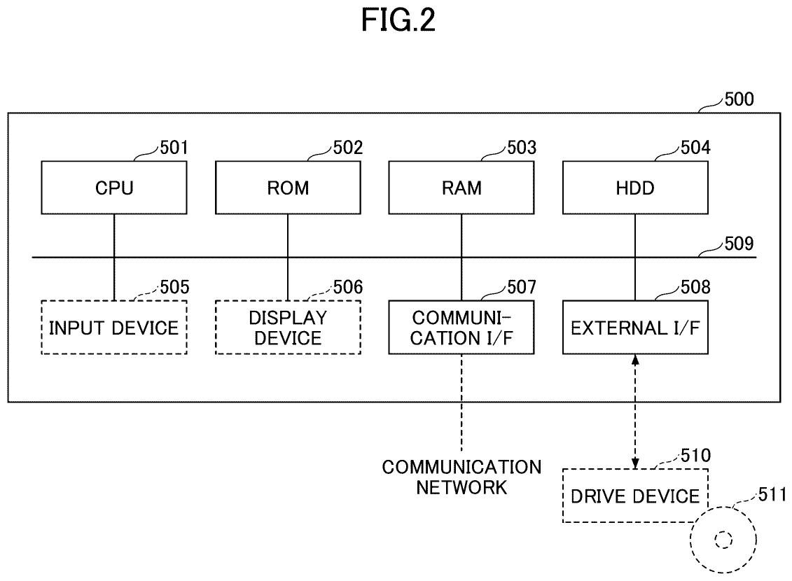

A hardware configuration of each device included in the temporal logic formula analysis system 1 of the present embodiment will be described with reference to FIG. 2.

### (Hardware Configuration of Computer)

The analysis apparatus 10 and the user device 20 in the present embodiment are realized by, for example, computers. FIG. 2 is a block diagram illustrating an example of the hardware configuration of the computer in the present embodiment.

As illustrated in FIG. 2, a computer 500 in the present embodiment includes a CPU (central processing unit) 501, a ROM (read-only memory) 502, a RAM (random-access memory) 503, an HDD (hard disk drive) 504, an input device 505, a display device 506, a communication interface (I/F) 507, and an external I/F 508. The CPU 501, the ROM 502, and the RAM 503 form a so-called computer. The hardware of the computer 500 is connected to each other via a bus line 509. The input device 505 and the display device 506 may be used by being connected to the external I/F 508.

The CPU 501 is an arithmetic calculating device that reads programs and data from a storage device, such as the ROM 502 or the HDD 504, onto the RAM 503 and executes processing to realize the control and functions of the entire computer 500. The computer 500 may have a GPU (graphics processing unit) in addition to the CPU 501 or in place of the CPU 501.

The ROM 502 is an example of a non-volatile semiconductor memory (storage device) where programs and data are preserved even when power is switched off. The ROM 502 functions as a main storage device that stores various programs and data necessary for the CPU 501 to execute various programs installed in the HDD 504. Specifically, the ROM 502 stores boot programs such as BIOS (basic input/output system) and EFI (extensible firmware interface) that are executed when the computer 500 is started, and data such as OS (operating system) settings and network settings.

The RAM 503 is an example of a volatile semiconductor memory (storage device) where programs and data are lost when power is switched off. The RAM 503 is, for example, a DRAM (dynamic random access memory) or SRAM (static random access memory). The RAM 503 provides a working area where various programs installed in the HDD 504 are loaded and executed by the CPU 501.

The HDD 504 is an example of a non-volatile storage device that stores programs and data. The programs and data stored in the HDD 504 include an OS, which is a basic software that controls the entire computer 500, and applications running on the OS to provide various functions. The computer 500 may use a storage device using a flash memory as a storage medium (e.g., a solid state drive (SSD), etc.) instead of the HDD 504.

The input device 505 is a touch panel, operation keys, buttons, a keyboard, a mouse, all of which are used by a user to input various signals, or a microphone to input sound data such as sound.

The display device 506 is composed of a display for displaying a screen, such as organic EL (electro-luminescence) display and a liquid crystal display, and a speaker for outputting sound data such as sound.

The communication I/F 507 is an interface for connecting to a communication network and for the computer 500 to perform data communication.

The external I/F 508 is an interface with an external device. The external device includes a drive device 510, etc.

The drive device 510 is a device for setting a recording medium 511. The recording medium 511 herein includes a medium for recording information optically, electrically, or magnetically, such as a CD-ROM, flexible disk, magneto-optical disk, or the like. The recording medium 511 may also include a semiconductor memory for recording information electrically, such as a ROM, flash memory, or the like. Thus, the computer 500 can read or write or read and write data from and to the recording medium 511 via the external I/F 508.

Various programs are installed on the HDD 504, for example, when the distributed recording medium 511 is set in the drive device 510 connected to the external I/F 508, and various programs recorded on the recording medium 511 are read by the drive device 510. Alternatively, various programs may be installed on the HDD 504 by downloading from another network different from the communication network via the communication I/F 507.

### <Functional Configuration of Temporal Logic Formula Analysis System>

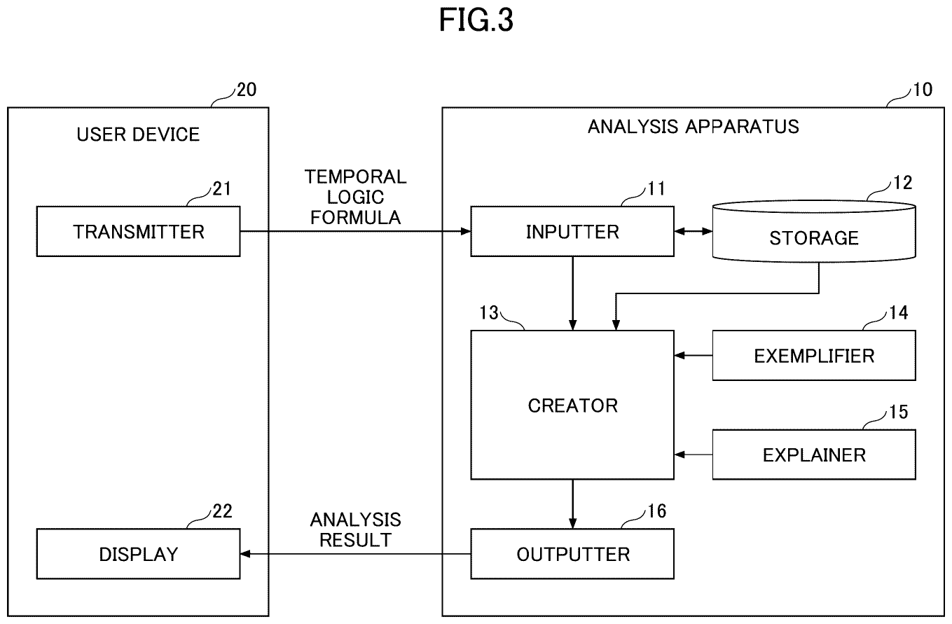

A functional configuration of the temporal logic formula analysis system of the present embodiment will be described with reference to FIG. 3. FIG. 3 is a block diagram illustrating an example of the functional configuration of the temporal logic formula analysis system of the present embodiment.

### (Functional Configuration of Analysis Apparatus)

As illustrated in FIG. 3, the analysis apparatus 10 of the present embodiment includes an inputter 11, a storage 12, a creator 13, an exemplifier 14, an explainer 15, and an outputter 16.

The inputter 11, the storage 12, the creator 13, the exemplifier 14, the explainer 15, and the outputter 16 are realized by, for example, loading a program from the HDD 504 illustrated in FIG. 2 into the RAM 503 also illustrated in FIG. 2 and executing the program by the CPU 501.

The inputter 11 receives an input of a temporal logic formula. The inputter 11 may receive an input of a temporal logic formula by receiving a temporal logic formula from the user device 20. The inputter 11 may receive a temporal logic formula that is input by a user to the input device 505 of the analysis apparatus 10.

The inputter 11 in the present embodiment is capable of receiving an input of two temporal logic formulae. Such two temporal logic formulae may include, for example, a temporal logic formula that is input by a user (an example of the first temporal logic formula) and a temporal logic formula revised from the first temporal logic formula (an example of the second temporal logic formula). Two temporal logic formulae may be two temporal logic formulae that are input separately by the same user or different users.

Screen data for displaying an analysis screen provided by the analysis tool is stored in advance in the storage 12. The screen data may be electronic data written in HTML (hypertext markup language) or the like, and may include applications written in JavaScript (registered trademark) or the like.

The temporal logic formula received by the inputter 11 is temporarily stored in the storage 12. The temporal logic formula stored in the storage 12 may be used as a first temporal logic formula or a second temporal logic formula in accordance with a user's instruction.

The creator 13 creates an analysis result to be displayed on the analysis tool based on the temporal logic formula received by the inputter 11 or the temporal logic formula read from the storage 12. The analysis result includes data obtained by converting the temporal logic formula into a display mode that facilitates user understanding. The analysis result may include data generated by the exemplifier 14 or the explainer 15.

The analysis result in the present embodiment is a block diagram in which the temporal logic formula to be analyzed is shown with a plurality of functional blocks representing respective elements and linked by lines. In the case where two temporal logic formulae are input, the analysis result in the present embodiment includes two block diagrams for showing the two temporal logic formulae in a comparable manner.

The exemplifier 14 generates a continuous time-varying signal (hereinafter referred to as “exemplification signal”) that makes the temporal logic formula to be analyzed true. The exemplification signal generated by the exemplifier 14 is output to the user device 20 as a part of the analysis result.

The exemplifier 14 in the present embodiment realizes an exemplification function for exemplifying semantic meaning of a temporal logic formula. The exemplification function takes a temporal logic formula φ as an input and outputs a continuous time-varying signal σ that makes the temporal logic formula φ true. In other words, the exemplification function generates a continuous time-varying signal σ that makes [σ, φ] greater than 0, where [σ, φ] represents a quantified Boolean value of the temporal logic formula φ in the continuous time-varying signal σ.

The explainer 15 calculates the quantified Boolean value (hereinafter referred to as “explanation information”) of the temporal logic formula to be analyzed based on a continuous time-varying signal (hereinafter referred to as “explanation signal”) selected by the user. The explanation information calculated by the explainer 15 is output to the user device 20 as a part of the analysis result.

The explainer 15 in the present embodiment realizes an explanation function for explaining semantic meaning of a temporal logic formula. The explanation function takes a temporal logic formula φ and a continuous time-varying signal σ as inputs, and outputs a quantified Boolean value [σ, φ] of the temporal logic formula φ in the continuous time-varying signal σ. The explanation function may output not only the quantified Boolean value [σ, φ] but also information indicating a reason how the temporal logic formula φ gives the quantified Boolean value. The information indicating the reason may be, for example, an element of the continuous time-varying signal σ having a large influence on the quantified Boolean value [σ, φ].

The outputter 16 embeds the analysis result created by the creator 13 into the screen data of the analysis screen that is read from the storage 12. The outputter 16 may embed the exemplification signal generated by the exemplifier 14 or the explanation information generated by the explainer 15 into the screen data. The outputter 16 transmits the screen data in which the analysis result is embedded to the user device 20.

### (Functional Configuration of User Device)

As illustrated in FIG. 3, the user device 20 in the present embodiment includes a transmitter 21 and a display 22.

The transmitter 21 and the display 22 are realized, for example, by processing that a program loaded from the HDD 504 into the RAM 503 causes the CPU 501 to execute, all of which are illustrated in FIG. 2.

The transmitter 21 acquires the temporal logic formula that is input by the user into the input device 505 of the user device 20. The transmitter 21 transmits the acquired temporal logic formula to the analysis apparatus 10.

The display 22 receives the screen data of the analysis screen from the analysis apparatus 10. The display 22 causes the display device 506 to display the analysis screen in which the analysis result of the temporal logic formula is embedded, based on the received screen data.

### <Analysis Screen>

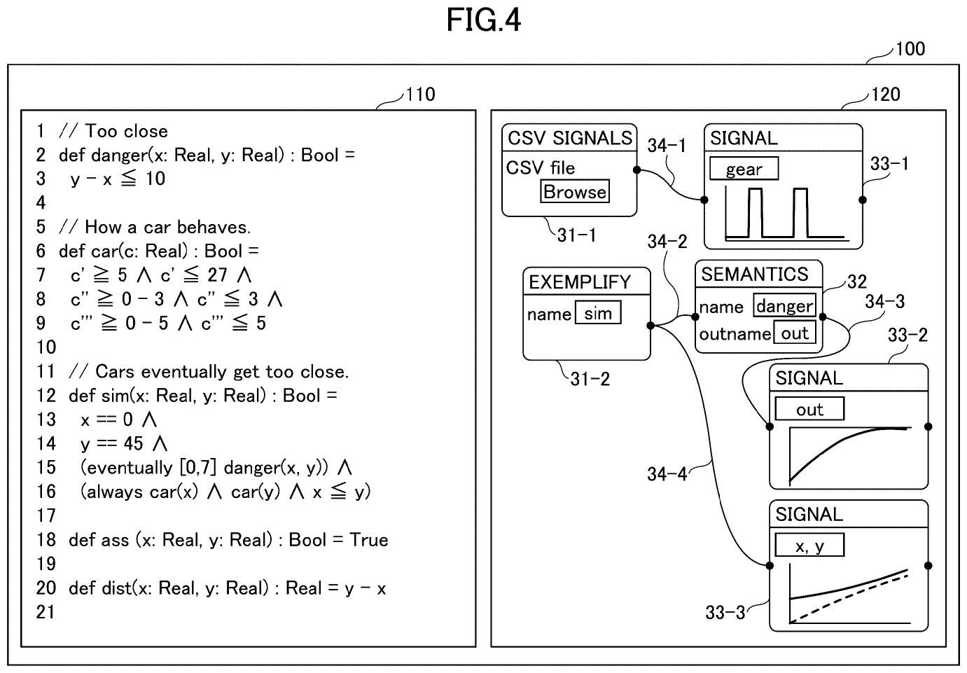

The analysis screen in the present embodiment will be described with reference to FIGS. 4 to 7. FIG. 4 is a view illustrating an example of the analysis screen in the present embodiment.

As illustrated in FIG. 4, an analysis screen 100 in the present embodiment has an input area 110 and a display area 120.

The input area 110 is an area where the user inputs a temporal logic formula. The input area 110 may be, for example, an editor specialized in temporal logic formulae. The editor has a function for efficiently inputting temporal logic formulae. The function includes, for example, a function for automatically complementing defined functions or operators, and a function for improving visibility by formatting or coloring an input temporal logic formula.

The display area 120 is an area for displaying an analysis result of the temporal logic formula that is input to the input area 110. The analysis result of the temporal logic formula includes a block diagram in which the temporal logic formula is shown by connecting a plurality of functional blocks representing respective elements.

### (Details of Block Diagrams)

The block diagram includes an input block, a formula block, and an output block as functional blocks. The input block indicates an input signal of a temporal logic formula. The formula block indicates content of a temporal logic formula. The output block indicates an output signal of a temporal logic formula. In the present embodiment, both an input signal and an output signal of a temporal logic formula are a continuous time-varying signal.

On the analysis screen 100 illustrated in FIG. 4, two input blocks 31-1 and 31-2, one formula block 32, and three output blocks 33-1 through 33-3 are displayed in the display area 120. The input block 31-1 and the output block 33-1 are connected by a link 34-1. The input block 31-2 and the formula block 32 are connected by a link 34-2. The formula block 32 and the output block 33-2 are connected by a link 34-3. The input block 31-2 and the output block 33-3 are connected by a link 34-4.

The link 34 connecting the input block 31 and the formula block 32 indicates that the input signal that is set in the input block 31 is input to the temporal logic formula that is set in the formula block 32. The link 34 connecting the formula block 32 and the output block 33 indicates that the output signal illustrated in the output block 33 is output from the temporal logic formula that is set in the formula block 32. The link 34 connecting the input block 31 and the output block 33 indicates that the content of the input signal that is set in the input block 31 is shown in the output block 33.

### (Details of Output Blocks)

The output block 33 shows a temporal change of an output signal on a graph having a time axis. The temporal logic formulae are a language that expresses properties of time-series data. Being able to visually recognize a temporal change of an input signal or an output signal makes it easier for the user to intuitively understand semantic meaning of a temporal logic formula.

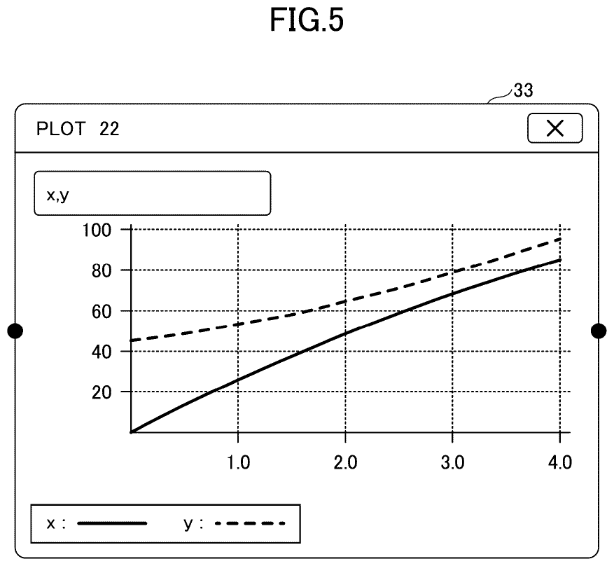

FIG. 5 is a diagram illustrating an example of the output block in the present embodiment. As illustrated in FIG. 5, the output block 33 in the present embodiment shows a graph in which the horizontal axis represents time and the vertical axis represents values. The graph shows the temporal change of the variables x and y included in the temporal logic formula.

### (Comparison of Temporal Logic Formulae)

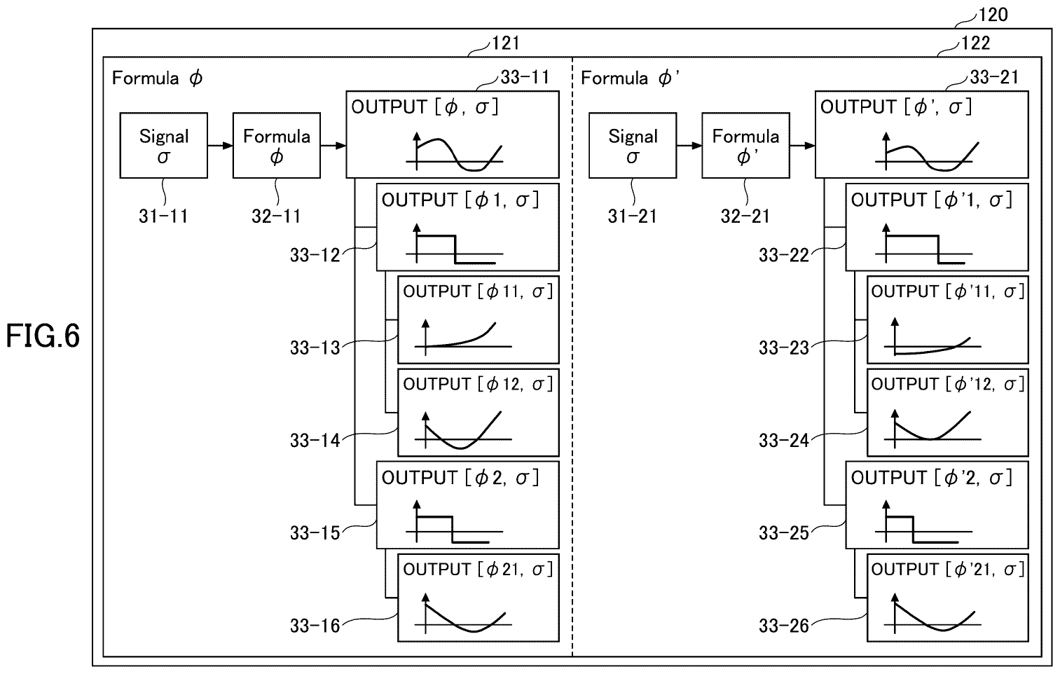

When two temporal logic formulae are input to the input area 110, the display area 120 displays the two temporal logic formulae in a comparable manner. FIG. 6 is a diagram illustrating an example of the display areas that display two temporal logic formulae.

As illustrated in FIG. 6, to display two temporal logic formulae, the display area 120 is divided into a first display area 121 and a second display area 122. The first display area 121 displays a first block diagram showing a first temporal logic formula (Formula φ). The second display area 122 displays a second block diagram showing a second temporal logic formula (Formula φ′).

The first block diagram includes an input block 31-11 showing an input signal (Signal σ), a formula block 32-11 showing the first temporal logic formula (Formula φ), and an output block 33-11 showing an output signal [φ, σ] at the time when the input signal σ is input to the first temporal logic formula φ. The first block diagram further includes a plurality of output blocks 33-12 through 33-16 showing the output signals [φ1, σ], [φ2, σ], [φ11, σ], [φ12, σ], and [φ21, σ] of the subformulae φ1, φ2, φ11, @12, and φ21 included in the first temporal logic formula φ.

The output blocks 33-12 through 33-16 showing the output signals of the subformulae are connected in a tree structure to the output block 33-11 showing the output signal of the first temporal logic formula. The tree structure illustrates an inclusion relationship of the subformulae in the first temporal logic formula. FIG. 6 illustrates an example of a tree structure in the case where the first temporal logic formula φ includes the subformulae φ1 and φ2, the subformulae φ1 includes the subformulae φ11 and φ12, and the subformula φ2 includes the subformula φ21.

The second block diagram includes, similarly to the first block diagram, an input block 31-21 showing an input signal (Signal σ), a formula block 32-21 showing the second temporal logic formula (Formula φ′), and an output block 33-21 showing an output signal [φ′, σ] at the time when the input signal σ is input to the second temporal logic formula φ′. The second block diagram further includes a plurality of output blocks 33-22 through 33-26 showing the output signals [φ′1, σ], [φ′2, σ], [φ′11, σ], [φ′12, σ], and [φ′21, σ] of the subformulae φ′1, φ′2, φ′11, φ′12, and φ′21 included in the second temporal logic formula o′.

The output blocks 33-22 through 33-26 are connected in a tree structure representing the inclusion relationship of the subformulae φ′1, φ′2, φ′11, φ′12, and φ′21.

In the first block diagram and the second block diagram, the input block, the formula block, and the output blocks are displayed in such a manner that the relative positional relationships of these blocks coincide between the first block diagram and the second block diagram. In the example of FIG. 6, the input block 31-11 of the first display area 121 and the input block 31-21 of the second display area 122 are arranged at relatively the same positions. Being “arranged at relatively the same positions” herein means that a position (e.g., an xy coordinate) relative to a predetermined origin (e.g., the center of the display area) that is set in one display area corresponds to that in the other.

Similarly, the formula block 32-11 of the first display area 121 and the formula block 32-21 of the second display area 122 are arranged at relatively the same positions. The output blocks 33-11 through 33-16 of the first display area 121 and the output blocks 33-21 through 33-26 of the second display area 122 are arranged at relatively the same positions.

The tree structure showing the inclusion relationship of the subformulae can be expanded and collapsed. When the user performs a predetermined operation (clicking, tapping, etc.) on any of the output blocks, the expanded/collapsed state of the tree structure is switched. For example, when the user clicks the output block 33-11 showing the first temporal logic formula while the tree structure of the output blocks 33-11 through 33-16 is expanded, the tree structure connected to the lower part of the output block 33-11 may be collapsed. For example, when the user clicks the output block 33-11 showing the first temporal logic formula while the tree structure of the output blocks 33-11 through 33-16 is collapsed, the tree structure connected to the lower part of the output block 33-11 may be expanded.

In the expansion and collapse of the tree structure, the tree structure below the manipulated output block 33 may be expanded and collapsed collectively. In the expansion and collapse of the tree structure, only the tree structure immediately below the manipulated output block 33 may be expanded and collapsed.

### (Difference of Temporal Logic Formulae)

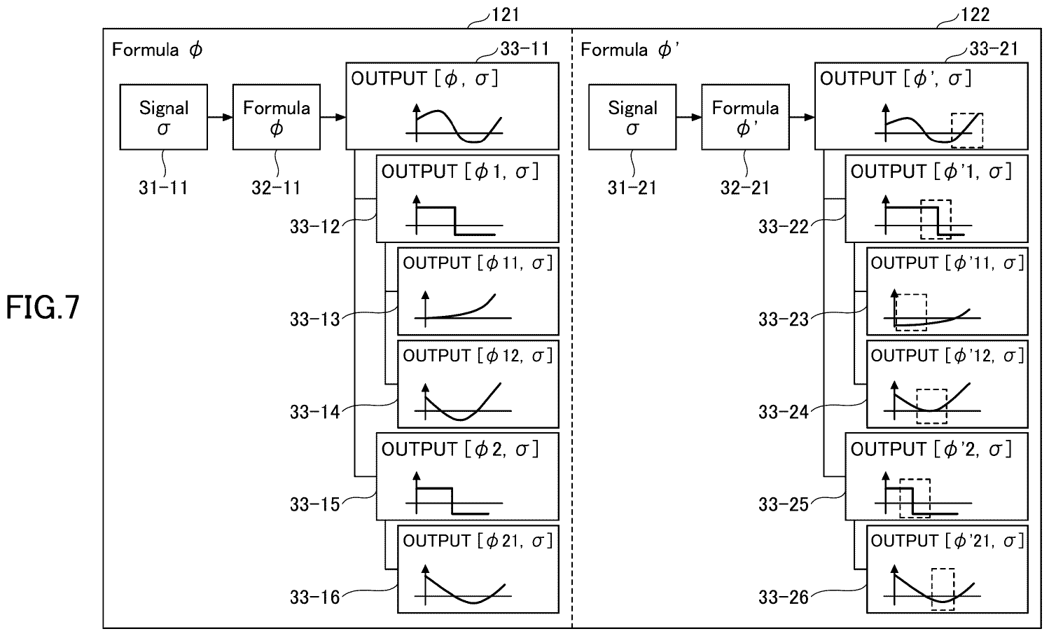

When two temporal logic formulae in a comparable manner are displayed on the display area 120, the difference between the two temporal logic formulae is shown with emphasis. FIG. 7 is a diagram illustrating an example of the display area for displaying a difference between the two temporal logic formulae.

As illustrated in FIG. 7, the output blocks 33-21 through 33-26 displayed in the second display area 122 are shown with emphasis indicating a difference in the waveform from the output blocks 33-11 through 33-16, which are displayed at relatively the same position in the first display area 121 as those in the second display area 122. The portion where the waveform differs between the output blocks 33-11 through 33-16 in the first display area 121 and the output blocks 33-21 through 33-26 in the second display area 122 contributes to the difference in Boolean values between the first temporal logic formula φ and the second temporal logic formula φ′. In the example illustrated in FIG. 7, the range that contributes to the difference in Boolean values is surrounded by a dashed rectangle for emphasis; however, the method of emphasizing can be discretionarily selected. For example, the portion that contributes to the difference in Boolean values may be shown with a bold line, or the portion that contributes to the difference in Boolean values versus other portions may be shown with color coding.

Compared to showing a difference in propositional logic, which is more widely used, showing a difference in output signals in temporal logic has an advantage, because the latter allows the user to track a time interval in detail that contributes to a difference. In order to analyze a difference between two temporal logic formulae, it is necessary to identify a portion in each subformula included in the temporal logic formulae that causes a difference in semantic meaning of the temporal logic formulae while the temporal causality of semantic meanings of the temporal logic formulae is tracked. To track the temporal causality, the calculation needs to start from the temporal logic formulae φ and φ′ at the top, proceed to a subformula immediately below, and then to a further lower subformula, based on the semantics of temporal logic.

Showing a difference between two temporal logic formulae with emphasis allows the user to track a time interval in detail that contributes to a difference in Boolean values of the two temporal logic formulae. For example, in FIG. 7, in the output blocks 33-21 through 33-26 displayed in the second display area 122, the time interval that contributes to the difference in the Boolean values is shown with emphasis by a dashed rectangle. With this configuration, the user can obtain a suggestion that the user only needs to pay attention to the emphasized time interval when analyzing the difference between the two temporal logic formulae.

In the block diagram displayed in the display area 120, the arrangement of functional blocks can be changed at a user's discretion. When the user selects (by clicking, tapping, etc.) any functional block in the display area 120 and moves (by dragging, etc.) to a freely selected position, the functional block is fixed at the position to which it has been moved, and the other functional blocks or links are rearranged at easily recognizable positions.

In the case where two block diagrams are displayed in a comparable manner in the display area 120, when the position of any functional block is changed in either one of the block diagrams, the corresponding functional block may be moved to relatively the same position in the other block diagram.

### <Processing Procedure of Temporal Logic Formula Analysis System>

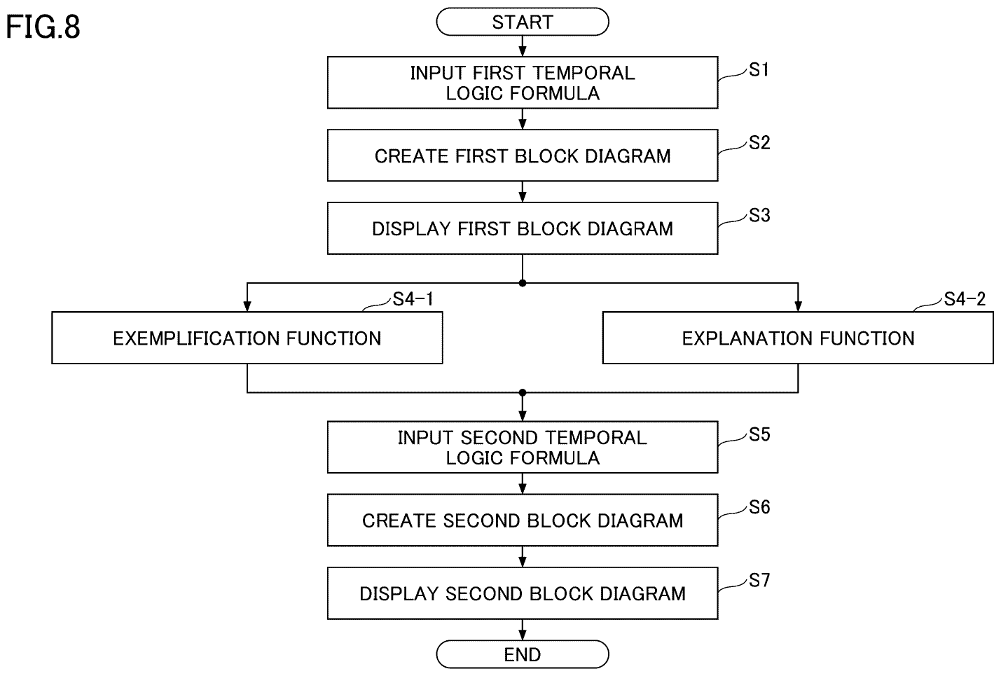

An analysis method executed by the temporal logic formula analysis system 1 of the present embodiment will be described with reference to FIG. 8. FIG. 8 is a flowchart illustrating an example of an analysis method in the present embodiment.

In step S1, the user device 20 causes the display device 506 to display the analysis screen 100 of the analysis tool. The user inputs a first temporal logic formula to be analyzed into the input area 110 of the analysis screen 100. The user may input a first temporal logic formula by loading electronic data that contains temporal logic formulae prepared in advance. Alternatively, the user may input a first temporal logic formula by operating the input device 505 of the user device 20.

The transmitter 21 of the user device 20 acquires the first temporal logic formula that is input by the user. Next, the transmitter 21 transmits the acquired first temporal logic formula to the analysis apparatus 10.

In the analysis apparatus 10, the inputter 11 receives the first temporal logic formula from the user device 20. Next, the inputter 11 accepts an input of the received first temporal logic formula. Subsequently, the inputter 11 causes the storage 12 to store the received first temporal logic formula. At this time, the inputter 11 generates unique identification information that does not overlap with other temporal logic formulae stored in the storage 12, and associates it with the first temporal logic formula. Then, the inputter 11 sends the first temporal logic formula to the creator 13.

In step S2, the creator 13 of the analysis apparatus 10 receives the first temporal logic formula from the inputter 11. Next, the creator 13 creates a first block diagram showing the first temporal logic formula. Then, the creator 13 sends the first block diagram to the outputter 16.

In step S3, the outputter 16 of the analysis apparatus 10 receives the first block diagram from the creator 13. Next, the outputter 16 reads the screen data of the analysis screen 100 from the storage 12. Subsequently, the outputter 16 embeds the first block diagram in the read screen data. Next, the outputter 16 causes the storage 12 to store the screen data in which the first block diagram is embedded. Then, the outputter 16 transmits the screen data in which the first block diagram is embedded to the user device 20.

In the user device 20, the display 22 receives the screen data in which the first block diagram is embedded from the analysis apparatus 10. Next, the display 22 updates the analysis screen 100 of the analysis tool based on the received screen data. Thus, the analysis screen 100 including the first block diagram is displayed on the display device 506 of the user device 20.

In step S4-1, the user performs an operation to execute the exemplification function with respect to the first block diagram displayed on the analysis screen 100. The transmitter 21 of the user device 20 transmits a control signal instructing execution of the exemplification function to the analysis apparatus 10. The control signal includes the first temporal logic formula or identification information of the first temporal logic formula.

In the analysis apparatus 10, the exemplifier 14 receives the control signal instructing execution of the exemplification function. In the case where the control signal includes the first temporal logic formula, the exemplifier 14 acquires the first temporal logic formula from the control signal. In the case where the control signal includes identification information, the exemplifier 14 reads the first temporal logic formula stored in the storage 12 based on the identification information.

The exemplifier 14 generates an exemplification signal that makes the acquired first temporal logic formula true. Next, the exemplifier 14 sends the generated exemplification signal to the creator 13.

The creator 13 receives the first temporal logic formula and the exemplification signal from the exemplifier 14. Next, the creator 13 sets the received exemplification signal in the input block of the first block diagram. The output block of the first block diagram is thereby updated so as to show the output signal at the time when the exemplification signal is input to the first temporal logic formula. Then, the creator 13 sends the first block diagram in which the exemplification signal is set to the outputter 16.

The outputter 16 receives the first block diagram from the creator 13. Next, the outputter 16 embeds the first block diagram in the screen data of the analysis screen 100. Then, the outputter 16 transmits the screen data in which the first block diagram is embedded to the user device 20.

In the user device 20, the display 22 receives the screen data in which the first block diagram is embedded from the analysis apparatus 10. Next, the display 22 updates the analysis screen 100 of the analysis tool based on the received screen data. Thus, the analysis screen 100 including the first block diagram in which the exemplification signal is set is displayed on the display device 506 of the user device 20.

In step S4-2, the user performs an operation to execute the explanation function with respect to the first block diagram displayed on the analysis screen 100. The transmitter 21 of the user device 20 transmits a control signal instructing execution of the explanation function to the analysis apparatus 10. The control signal includes the first temporal logic formula or identification information of the first temporal logic formula, and an explanation signal, which is a target of explanation.

The explanation signal is a continuous time-varying signal prepared in advance by the user. The explanation signal may be real data observed in the system to be developed. The explanation signal may be an exemplification signal generated using the exemplification function. The explanation signal may be a pseudo signal generated by the user using an applicable analysis tool. The explanation signal may be prepared by a person other than the user of the analysis tool (for example, a developer who develops the system in conjunction).

In the analysis apparatus 10, the explainer 15 receives the control signal instructing execution of the explanation function. In the case where the control signal includes the first temporal logic formula, the explainer 15 acquires the first temporal logic formula from the control signal. In the case where the control signal includes identification information, the explainer 15 reads the first temporal logic formula stored in the storage 12 based on the identification information.

The explainer 15 calculates the explanation information of the first temporal logic formula based on the explanatory signal included in the control signal. Next, the explainer 15 sends the generated explanation information to the creator 13.

The creator 13 receives the first temporal logic formula and the explanation information from the explainer 15. Next, the creator 13 sets an explanatory signal in the input block of the first block diagram, and sets the received explanation information in the output block of the first block diagram. Then, the creator 13 sends the first block diagram in which the explanation information is set to the outputter 16.

The outputter 16 receives the first block diagram from the creator 13. Next, the outputter 16 embeds the first block diagram in the screen data of the analysis screen 100. Then, the outputter 16 transmits the screen data in which the first block diagram is embedded to the user device 20.

In the user device 20, the display 22 receives the screen data in which the first block diagram is embedded from the analysis apparatus 10. Next, the display 22 updates the analysis screen 100 of the analysis tool based on the received screen data. Thus, the analysis screen 100 including the first block diagram in which the explanation information is set is displayed on the display device 506 of the user device 20.

In step S5, the user inputs a second temporal logic formula to be analyzed into the input area 110 of the analysis screen 100. The user may input a second temporal logic formula by editing the first temporal logic formula that has been input in the input area 110 of the analysis screen 100. Alternatively, the user may input a second temporal logic formula by loading electronic data that contains temporal logic formulae prepared in advance.

The transmitter 21 of the user device 20 acquires the second temporal logic formula that is input by the user. Next, the transmitter 21 transmits the acquired second temporal logic formula to the analysis apparatus 10.

In the analysis apparatus 10, the inputter 11 receives the second temporal logic formula from the user device 20. Next, the inputter 11 accepts an input of the received second temporal logic formula. Subsequently, the inputter 11 causes the storage 12 to store the received second temporal logic formula. At this time, the inputter 11 generates unique identification information that does not overlap with other temporal logic formulae stored in the storage 12, and associates it with the second temporal logic formula. Then, the inputter 11 sends the second temporal logic formula to the creator 13.

The user may select the second temporal logic formula from the temporal logic formulae stored in the storage 12 in the analysis apparatus 10. In this case, first, the user device 20 causes the display device 506 to display a list of the temporal logic formulae stored in the storage 12 of the analysis apparatus 10. In response to the user's operation of selecting a temporal logic formula, the transmitter 21 transmits identification information associated with the selected temporal logic formula to the analysis apparatus 10.

In the analysis apparatus 10, the inputter 11 receives the identification information of the temporal logic formula from the user device 20. Next, the inputter 11 reads the temporal logic formula stored in the storage 12 based on the received identification information. Then, the inputter 11 sends the read temporal logic formula to the creator 13.

In step S6, the creator 13 of the analysis apparatus 10 receives the second temporal logic formula from the inputter 11. Next, the creator 13 creates a second block diagram showing the second temporal logic formula. Then, the creator 13 sends the second block diagram to the outputter 16.

In step S7, the outputter 16 of the analysis apparatus 10 receives the second block diagram from the creator 13. Next, the outputter 16 reads the screen data in which the first block diagram is embedded from the storage 12. Subsequently, the outputter 16 embeds the second block diagram in the read screen data. Then, the outputter 16 transmits the screen data in which the first block diagram and the second block diagram are embedded to the user device 20.

In the user device 20, the display 22 receives the screen data in which the first block diagram and the second block diagram are embedded from the analysis apparatus 10. Next, the display 22 updates the analysis screen 100 of the analysis tool based on the received screen data. Thus, the analysis screen 100 including the first block diagram and the second block diagram is displayed on the display device 506 of the user device 20.

In the analysis screen 100, the first block diagram and the second block diagram are displayed on the display area 120 in a comparable manner. For example, on the display area 120 of the analysis screen 100, the first display area 121 for displaying the first block diagram and the second display area 122 for displaying the second block diagram are displayed aligned. At this time, the first block diagram and the second block diagram are displayed in such a manner that the relative positional relationship of the input block, formula block, and output blocks in the first block diagram coincides with the relative positional relationship of the input block, formula block, and output blocks in the second block diagram.

### Effects of Embodiment

The analysis apparatus 10 of the present embodiment outputs an analysis screen that displays a first block diagram showing semantic meaning of a first temporal logic formula and a second block diagram showing semantic meaning of a second temporal logic formula in a comparable manner. Therefore, according to the analysis apparatus 10 of the present embodiment, since two temporal logic formulae can be easily compared, temporal logic formulae can be efficiently analyzed.

The first block diagram in the present embodiment is a block diagram in which an input block showing an input signal, a formula block showing a first temporal logic formula, and an output block showing an output signal at the time when an input signal is input to the first temporal logic formula are linked. The second block diagram is a block diagram in which an input block showing an input signal, a formula block showing a second temporal logic formula, and an output block showing an output signal at the time when an input signal is input to the second temporal logic formula are linked. Therefore, according to the analysis apparatus 10 of the present embodiment, two temporal logic formulae can be intuitively compared.

The analysis apparatus 10 of the present embodiment shows the first block diagram and the second block diagram in such a manner that the relative positional relationship of the input block, formula block, and output blocks in the first block diagram coincides with the relative positional relationship of the input block, formula block, and output blocks in the second block diagram. Therefore, according to the analysis apparatus 10 of the present embodiment, a difference between two temporal logic formulae can be intuitively understood.

The analysis apparatus 10 according to the present embodiment causes the output block to show a temporal change of an output signal on a graph having a time axis. Since temporal logic formulae represent time-series data, allowing a user to check a temporal change of an output signal contributes to user understanding of semantic meaning of a temporal logic formula. Therefore, according to the analysis apparatus 10 according to the present embodiment, it is possible to output a screen that facilitates user understanding of semantic meaning of a temporal logic formula.

When an output block of the first block diagram and an output block of the second block diagram show different output signals, the analysis apparatus 10 according to the present embodiment shows a difference between the output signals on a graph. Therefore, according to the analysis apparatus 10 of the present embodiment, it is possible to output a screen that facilitates user understanding of a difference between temporal logic formulas.

The analysis apparatus 10 of the present embodiment changes the position of any one of the input block, formula block, or output blocks to a freely chosen position in response to a user's operation. Therefore, according to the analysis apparatus 10 of the present embodiment, temporal logic formulae can be intuitively compared at user-desired positions.

When the position of any one of the input block, formula block, or output blocks is changed in the first block diagram, the analysis apparatus 10 in the present embodiment changes the position of a corresponding one of the input block, formula block, or output blocks in the second block diagram so that the relative positional relationship in the first block diagram coincides with the relative positional relationship in the second block diagram. Therefore, according to the analysis apparatus 10 of the present embodiment, even in the case where the position is changed to a user-desired position, it is possible to output a screen that facilitates user understanding of a difference between temporal logic formulae.

According to the analysis apparatus 10 of the present embodiment, the output block includes one or more output blocks respectively showing output signals of one or more subformulae included in a temporal logic formula. A temporal logic formula can include one or more subformulae. Therefore, when there is a problem in an output of a temporal logic formula, if the subformula that is causing the problem can be identified, the problem can be efficiently solved. Therefore, according to the analysis apparatus 10 of the present embodiment, a problem that arises in a temporal logic formula can be efficiently solved.

In the analysis apparatus 10 of the present embodiment, the output blocks showing the output signals of the subformulae are connected in a tree structure that shows the inclusion relationship of the subformulae. When the user performs a predetermined operation on any one of the output blocks, the analysis apparatus 10 of the present embodiment switches the expanded/collapsed state of the tree structure. Since a complicated temporal logic formula includes many subformulae, it is efficient to switch the number of blocks displayed when the user checks output signals of the subformulae. Therefore, according to the analysis apparatus 10 of the present embodiment, output signals of a number of subformulae can be efficiently checked.

Since the analysis apparatus 10 of the present embodiment shows a difference between two temporal logic formulae in a mode that facilitates user understanding, the user can easily understand, for example, a difference between a temporal logic equation before revision and a temporal logic formula after revision. By repeating a revision of the temporal logic equation while checking analysis results, the user can efficiently create a temporal logic formula as intended. For example, if a temporal logic formula can be efficiently created in an analysis task that arises in a product design process, the product design can be efficiently advanced and the lead time of product development can be shortened.

### <Notes>

Each function of the above-described embodiment can be realized by one or more processing circuits. The term “processing circuit” as used herein includes a processor programmed to execute each function by software, such as a processor implemented by an electronic circuit, or equipment such as an ASIC (application specific integrated circuit), DSP (digital signal processor), FPGA (field programmable gate array), or conventional circuit module designed to execute each function described above.

Although the embodiments of the present disclosure have been described in detail above, the present disclosure is not limited to these embodiments, and may be modified or modified in various ways within the scope of the gist of the present disclosure described in the claims.

What is claimed is:

1. An analysis apparatus, comprising:
an inputter configured to receive an input of a first temporal logic formula and an input of a second temporal logic formula; and
an outputter configured to output a screen for displaying a first block diagram showing the first temporal logic formula and a second block diagram showing the second temporal logic formula in a comparable manner.

2. The analysis apparatus according to claim 1, wherein
the first block diagram includes an input block showing an input signal, a formula block showing the first temporal logic formula, and an output block showing an output signal at a time when the input signal is input to the first temporal logic formula, the input block, the formula block, and the output block being connected, and
the second block diagram includes an input block showing the input signal, a formula block showing the second temporal logic formula, and an output block showing an output signal at a time when the input signal is input to the second temporal logic formula, the input block, the formula block, and the output block being connected.

3. The analysis apparatus according to claim 2, wherein
the screen is caused to display the first block diagram and the second block diagram in such a manner that a relative positional relationship of the input block, the formula block, and the output block in the first block diagram coincides with a relative positional relationship of the input block, the formula block, and the output block in the second block diagram.

4. The analysis apparatus according to claim 2, wherein
the output block shows a temporal change of the output signal on a graph having a time axis.

5. The analysis apparatus according to claim 4, wherein
the screen is caused to display the graph on which a difference between the output signal shown in the output block of the first block diagram and the output signal shown by the output block of the second block diagram is shown.

6. The analysis apparatus according to claim 3, wherein
a position of any one of the input block, the formula block, or the output block displayed on the screen is changed in accordance with a user's operation.

7. The analysis apparatus according to claim 6, wherein
in the screen, when a position of any one of the input block, the formula block, or the output block is changed in the first block diagram, the position of a corresponding one of the input block, the formula block, or the output block in the second block diagram is changed so that the relative positional relationship in the first block diagram coincides with the relative positional relationship in the second block diagram.

8. The analysis apparatus according to claim 2, wherein
the first block diagram includes one or more output blocks respectively showing output signals of one or more subformulae included in the first temporal logic formula, and
the second block diagram includes one or more output blocks respectively showing output signals of one or more subformulae included in the second temporal logic formula.

9. The analysis apparatus according to claim 8, wherein
the one or more output blocks respectively showing the output signals of the subformulae are connected in a tree structure showing an inclusion relationship of the subformulae.

10. The analysis apparatus according to claim 9, wherein
on the screen, an expanded or collapsed state of the tree structure is switched when a user performs a predetermined operation on the output block.

11. The analysis apparatus according to claim 2, wherein
on the screen,
the output block of the first block diagram shows a continuous time-varying signal that makes the first temporal logic formula true, or
the output block of the second block diagram shows a continuous time-varying signal that makes the second temporal logic formula true.

12. The analysis apparatus according to claim 2, wherein
on the screen,
the output block of the first block diagram shows a Boolean value of the first temporal logic formula calculated using a continuous time-varying signal as an input, or
the output block of the second block diagram shows a Boolean value of the second temporal logic formula calculated using a continuous time-varying signal as an input.

13. An analysis method, comprising:
causing a computer to execute
receiving an input of a first temporal logic formula and an input of a second temporal logic formula; and
outputting a screen for displaying a first block diagram showing the first temporal logic formula and a second block diagram showing the second temporal logic formula in a comparable manner.

14. A non-transitory computer-readable storage medium storing a program for causing a computer to execute:
receiving an input of a first temporal logic formula and an input of a second temporal logic formula; and
outputting a screen for displaying a first block diagram showing the first temporal logic formula and a second block diagram showing the second temporal logic formula in a comparable manner.
